(19) United States
(12) Patent Application Publication
(10) Pub. No.: US 2026/0146874 A1
(43) Pub. Date: May 28, 2026

(54) INTEGRATED CIRCUIT FOR MEASURING MANIFOLD TEMPERATURE AND DETECTING LEAKS IN LIQUID-COOLED SERVERS

(71) Applicant: AMD Design, LLC, Wlimington, DE (US)

(72) Inventors: Rukang HUANG, East Williston, NY (US); Pruthvik RAGHUPATHI, Seattle, WA (US); Chen AN, Bergenfield, NJ (US); Sruti CHIGULLAPALLI, Seattle, WA (US)

(73) Assignee: AMD Design, LLC, Wilmington, DE (US)

(21) Appl. No.: 18/960,524

(22) Filed: Nov. 26, 2024

(51) Int. Cl. G01D 21/02; G01K 1/14; G01M 3/04; H05K 7/20

(52) U.S. Cl. CPC G01D 21/02; G01K 1/14; G01M 3/04; H05K 7/20272; H05K 7/20772; H05K 7/20836

(57) ABSTRACT

The integrated circuit includes a mounting portion configured to attach at least a portion of the integrated circuit to a manifold of a liquid-cooled server. The integrated circuit also includes a temperature sensor configured to detect a temperature of the manifold. The integrated circuit also includes a leak detection sensor configured to detect whether a liquid exists in an area proximate the manifold. The integrated circuit also includes a communication system configured to communicate the temperature of the manifold and/or whether the liquid exists in the area. The integrated circuit is a compact solution usable to determine information (e.g., inlet temperature, outlet temperature, differential temperatures, leaks, etc.) about a server in which it is implemented.

### FIELD

This disclosure is directed to liquid temperature determination and liquid leak detection in liquid-cooled servers.

### BACKGROUND

Many servers (e.g., cloud-computing servers, cloud servers, network servers, web servers, artificial intelligence (AI) servers, server blades, or switches) include liquid-cooling systems configured to transfer heat produced by components (e.g., processors) of the servers to a fluid that is pumped through the servers. While many of the components have means for detecting their own temperatures, it can often be beneficial to determine temperatures of the influent and effluent flows of the fluid. Doing so may enable root-cause analysis of high-temperature situations of the components. Furthermore, leak-detection of the fluid may also be beneficial in ensuring that the servers operate as designed. For example, leaks can cause short-circuits, failure of components, overheating of components, safety concerns, and other problems. As space is often very limited within servers, putting separate sensors for temperature detection and leak detection is often space prohibitive. Furthermore, separate systems often require dedicated wiring and connections which takes up further space in the servers.

### SUMMARY

Described herein is an integrated circuit. The integrated circuit includes a mounting portion configured to attach at least a portion of the integrated circuit to a manifold. The integrated circuit also includes a temperature sensor configured to detect a temperature of the manifold. The integrated circuit further includes a leak detection sensor configured to detect whether a liquid exists in an area proximate a component coupled with the manifold. The integrated circuit also includes a communication system configured to communicate the temperature of the manifold and whether the liquid exists in the area.

Also described herein is a server. The server includes a plurality of manifold assemblies that each include a manifold with a first port and one or more second ports in communication with the first port. Each of the manifold assemblies also includes the integrated circuit above.

Also described herein is a liquid control system. The liquid control system includes a processing system configured to receive an inlet temperature from an inlet integrated circuit attached to an inlet manifold within a server and receive an outlet temperature from an outlet integrated circuit attached to an outlet manifold within the server. The processing system is also configured to receive a processing system temperature of a processing system within the server. The processing system is further configured to, responsive to determining that the processing system temperature is above a threshold temperature, determine a possible cause of the processing system temperature being above the threshold based on at least one of the inlet temperature or the outlet temperature.

The foregoing summary is illustrative only and is not intended to be in any way limiting. In addition to the illustrative aspects, embodiments, and features described above, further aspects, embodiments, and features will become apparent by reference to the drawings and the following detailed description. In the drawings, like reference numbers indicate identical or functionally similar elements.

### BRIEF DESCRIPTION OF THE DRAWINGS

FIG. 1 illustrates an example of a server that includes an integrated circuit for measuring manifold temperature and detecting leaks in liquid-cooled servers.

FIG. 2A illustrates a first view of a first example of a manifold assembly that includes an integrated circuit for measuring manifold temperature and detecting leaks in liquid-cooled servers.

FIG. 2B illustrates a second view of the first example of the manifold assembly of FIG. 2A.

FIG. 3A illustrates a first view of a second example of a manifold assembly that includes an integrated circuit for measuring manifold temperature and detecting leaks in liquid-cooled servers.

FIG. 3B illustrates a second view of the second example of the manifold assembly of FIG. 2A.

FIG. 4 illustrates an example of a schematic of an integrated circuit for measuring manifold temperature and detecting leaks in liquid-cooled servers.

FIG. 5 illustrates an example process flow of root-cause analysis of high-temperature situations in liquid-cooled servers coupled to an integrated circuit for measuring manifold temperature and detecting leaks in liquid-cooled servers.

FIG. 6 illustrates an example liquid control system coupled to an integrated circuit for measuring manifold temperature and detecting leaks in liquid-cooled servers.

### DETAILED DESCRIPTION

### Overview

Liquid-cooling systems are commonly used in servers of all types to transfer heat produced by components within the servers outside of the servers. Many of the servers include temperature sensors and control systems that indicate when one or more components within the servers overheat (e.g., reach an OVER TEMP condition). However, the cause of the overheating components is often unknown. Furthermore, liquid-cooling systems often include leak-detection sensors to ensure that leaking components of the liquid-cooling systems do not cause problems within the servers. While additional sensors may help diagnose overheating conditions, adding more sensors to an already crowded server for things like additional temperature detection and leak detection may be space-prohibitive.

Described herein is an integrated circuit for measuring manifold temperature and detecting leaks in liquid-cooled servers. The integrated circuit includes a mounting portion configured to attach at least a portion of the integrated circuit to a manifold (e.g., fluid distribution or reception manifold). The integrated circuit also includes a temperature sensor configured to detect a temperature of the manifold. The integrated circuit also includes a leak detection sensor configured to detect whether a liquid exists in an area proximate a component coupled with the manifold. The integrated circuit also includes a communication system configured to communicate the temperature of the manifold and whether the liquid exists in the area. The integrated circuit is a compact solution to convey temperature and leak-detection information that may be used by a system (either the associated server or an external system) to determine various aspects of the liquid-cooling system of the associated server (e.g., inlet temperature, outlet temperature, flowrate of a liquid within the liquid-cooling system).

The integrated circuit may be formed as a flexible printed circuit board (PCB) or as a flex-rigid PCB (e.g., a PCB having a flex portion and a rigid portion). A portion of the PCB may be attached to an inlet manifold or an outlet manifold to detect, for example, an inlet temperature of a fluid, an outlet temperature of the fluid, and/or leaks of the fluid at the inlet manifold or outlet manifold.

The leak detection sensor may be remote to another portion of the integrated circuit and may be connected to the other portion via a cable or a portion of the integrated circuit that is configured to be wrapped around a manifold to detect leaks from a component attached to the manifold. For example, the leak detection sensor may be configured to be disposed within a container (e.g., a pan or tray) configured to contain leaks from ports of the manifold or associated components (e.g., fluid connectors).

The integrated circuit may include, or be configured to receive, a single connection cable. Because the temperature sensor and the leak detection sensor are combined into a single integrated circuit, the single connection cable may be configured to carry power and signals to and from the sensors and a controller, which may reduce an overall footprint of the sensor system. The controller (e.g., a baseboard management controller or BMC) may be part of the server and may be configured to perform actions based on the signals from the integrated circuit (e.g., generating alerts) and/or may relay the signals and/or data determined from the signals to a remote entity (e.g., a facility system).

In some implementations, a server may include multiple of the integrated circuits described herein. For example, a server may include one integrated circuit attached to an inlet manifold and another attached to an outlet manifold. Having both may enable measurement of a differential temperature between the inlet and outlet manifolds. By monitoring the differential temperature, deficiencies of a coolant distribution unit (CDU) providing coolant to the server, insufficient flow rates, and flow constrictions may be identified.

The integrated circuit and associated control system, as described herein, may provide multiple advantages compared to current solutions. For example, an identical solution for both inlet and outlet leak detection and temperature monitoring may be achieved within the server. Furthermore, manifold assemblies using the integrated circuits may also be the same between inlets and outlets.

The design of the integrated circuit may be compatible with different types of temperature sensors (e.g., diode-based thermistors, positive temperature coefficient (PTC) thermistors, negative temperature coefficient (NTC) thermistors). Furthermore, the temperature sensor and/or the leak detection sensor may be an active sensor or a passive sensor without departing from the scope of this disclosure.

The integrated circuit(s) may be located on a lowest-level subassembly of the server, while components requiring a higher frequency of maintenance, such as quick disconnects and cables, may be located in higher-level assemblies of the server. Such placements may ensure that maintenance of the higher-level assemblies will not affect the integrated circuit(s). Additionally, having the PCB of the integrated circuit wrap around a manifold provides a low-profile package without using much additional volume in the server tray.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

### Example Server

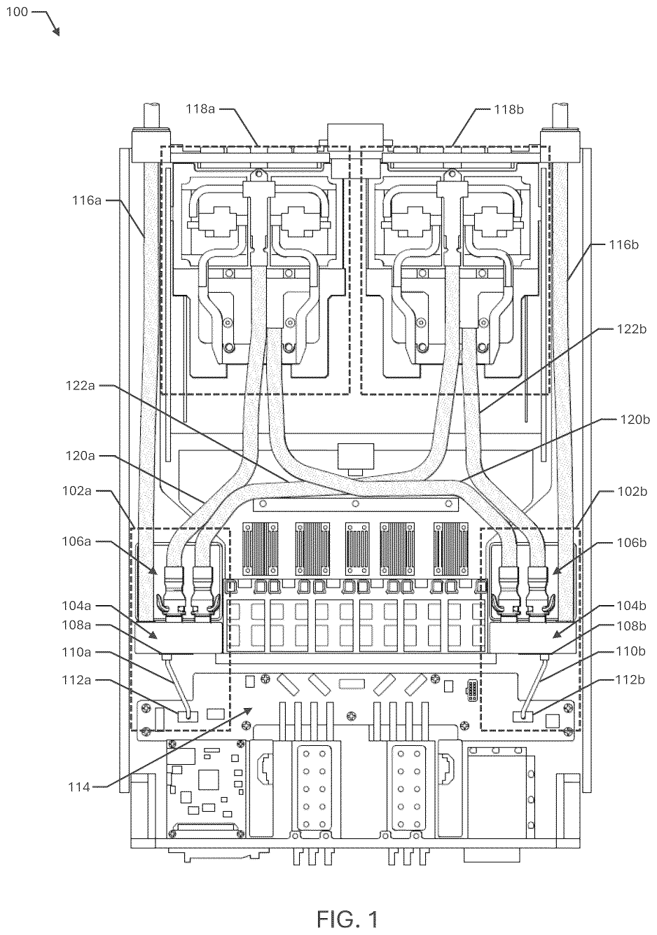

FIG. 1 illustrates an example of a server 100 that includes an integrated circuit for measuring manifold temperature and detecting leaks in liquid-cooled servers, in accordance with this disclosure. The server 100 may be any type of computing device (e.g., computer, server, network server, web server, artificial intelligence (AI) server, blade, or switch), the server 100 may be included in a server rack or stand alone.

The server 100 includes an inlet manifold assembly 102a. The inlet manifold assembly 102a includes a manifold 104a, a leak container 106a, and a PCB assembly 108a including an integrated circuit as described herein. The PCB assembly 108a includes a cable 110a and a connector 112a.

Likewise, the server 100 includes an outlet manifold assembly 102b. The outlet manifold assembly 102b includes a manifold 104b, a leak container 106b, and a PCB assembly 108b including the integrated circuit as described herein. The PCB assembly 108b includes a cable 110b and a connector 112b. Inlet manifold assembly 102a and outlet manifold assembly 102b are components of a liquid cooling system (not referenced) installed in the server 100.

The server 100 also includes a motherboard 114. The motherboard 114 may include a BMC or similar monitoring circuitry. Alternatively, the BMC or other monitoring circuitry may be external to the server 100. The motherboard communicates signals, either by the system bus, another communication bus (e.g., i2c) or by other wired or wireless means, between the BMC and the PCB assemblies 108a and 108b as well as power to the PCB assemblies 108a and 108b (as needed). The signals and power are communicated to and from the PCB assemblies 108a and 108b via the cables 110a and 110b, respectively, and the connectors 112a and 112b, respectively. The BMC in turn may be communicably coupled to a monitoring system (e.g., a cluster management system, a liquid control system) which may be internal to the server 100 or external to the server 100, for example, via an out of band network.

Liquid coolant is pumped into the manifold 104a via an inlet hose 116a and egresses from the manifold 104b via an exit hose 116b. The liquid coolant is routed from the manifold 104a to cold plates 118a and 118b through hoses 120a and 122a respectively. As the liquid coolant passes through the cold plates 118a and 118b, heat is transferred from components covered by the cold plates 118a and 118b to the liquid coolant. The liquid coolant is routed from the cold plates 118a and 118b to the manifold 104b by the hoses 120b and 122b respectively. Once the liquid coolant exits the server through the exit hose 116b, it may be circulated through a liquid control system or some other system that transfers the heat from the liquid coolant to the environment. It should be noted that influent and effluent components may be switched without departing from the scope of this disclosure.

In this example, the manifold 104a receives coolant from a coolant distribution unit (not shown) and routes the coolant proximate to one or more chips (e.g., central processing units (CPU), graphics processing units (GPU), artificial intelligence processors) included in the server 100. The coolant is further routed from being proximate to the one or more chips to the manifold 104b and then back to the CDU. Likewise, other liquid cooling methods or coolant routing may be implemented.

### Example Manifold Assemblies

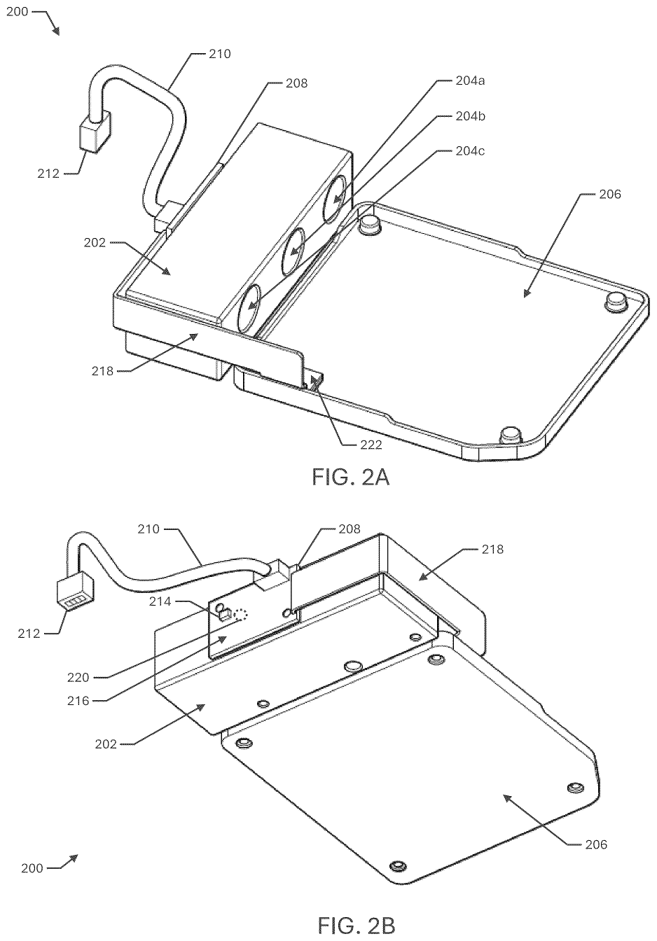

FIGS. 2A and 2B illustrate an example of a manifold assembly 200 that includes an integrated circuit for measuring manifold temperature and detecting leaks in liquid-cooled servers, in accordance with this disclosure. The manifold assembly 200 (e.g., the inlet manifold assembly 102a and the outlet manifold assembly 102b illustrated on FIG. 1) includes a manifold 202 having ports 204a, 204b, and 204c. In other implementations, the manifold 202 may have two ports or more than three ports. In this example, Port 204a is connected to tubing (not shown) that either routes liquid coolant into the manifold 202 from a source external to a server (e.g., server 100 illustrated in FIG. 1) if the manifold 202 is implemented as an inlet manifold or out of the server to a return external to the server if the manifold 202 is implemented as an outlet manifold. The ports 204b and 204c are connected to tubing that routes the coolant to or from chips, respective to the manifold being an inlet manifold or outlet manifold, internal to the server. In other implementations, the functionality of ports 204a, 204b, and 204c may be interchanged.

The manifold assembly 200 also includes a leak container 206 (e.g., the leak containers 106a and 106b illustrated in FIG. 1) and a PCB assembly 208 (e.g., the PCB assemblies 108a and 108b illustrated in FIG. 1). The PCB assembly 208 can be connected to a motherboard via a single cable 210 (e.g., the cables 110a and 110b illustrated in FIG. 1) and a connector 212 (e.g., the connectors 112a and 112b illustrated in FIG. 1).

The PCB assembly 208 illustrated in FIGS. 2A and 2B include an integrated circuit 214, a rigid portion 216 attached on one side of the manifold 202, and a flexible portion 218 that wraps around another side of the manifold 202. In some cases, the PCB assembly 208 may only have a rigid portion or may only have a flexible portion. Alternatively, the flexible portion 218 may be replaced with a cable (e.g., a ribbon cable connected to the rigid portion 216). The flexible portion 218 (or the ribbon cable in some examples) may be routed in a slot (not shown) on the manifold 202 configured such that the flexible portion 218 is flush with the outer surface of the manifold 202.

The integrated circuit includes a temperature sensor 220 (e.g., diode-based thermistors, positive temperature coefficient (PTC) thermistors, negative temperature coefficient (NTC) thermistors) in contact with the manifold 202, configured to detect a temperature of the manifold (and thus a temperature of the coolant liquid), and a communication system disposed on the rigid portion 216, and a leak detections sensor 222 disposed on the flexible portion 218. The temperature sensor 220 is configured to detect a temperature of the manifold. The leak detection sensor 222 is configured to detect whether a liquid exists in an area proximate to the leak container 206. The communication system is configured to communicate the temperature of the manifold 202 and whether liquid exists in the area. The temperature sensor 220 may be disposed on a same side of the manifold 202 as the leak detection sensor 222 (e.g., front, back, side, top, or bottom) or a different side.

Because the temperature sensor 220 and the leak detection sensor 222 are integrated together in a single package, the footprint of the assembly remains minimal and does not require excess volume within the server. Additionally, the single cable that connects the PCB assembly 208 to the motherboard further reduces the footprint compared to sensors with separate cables.

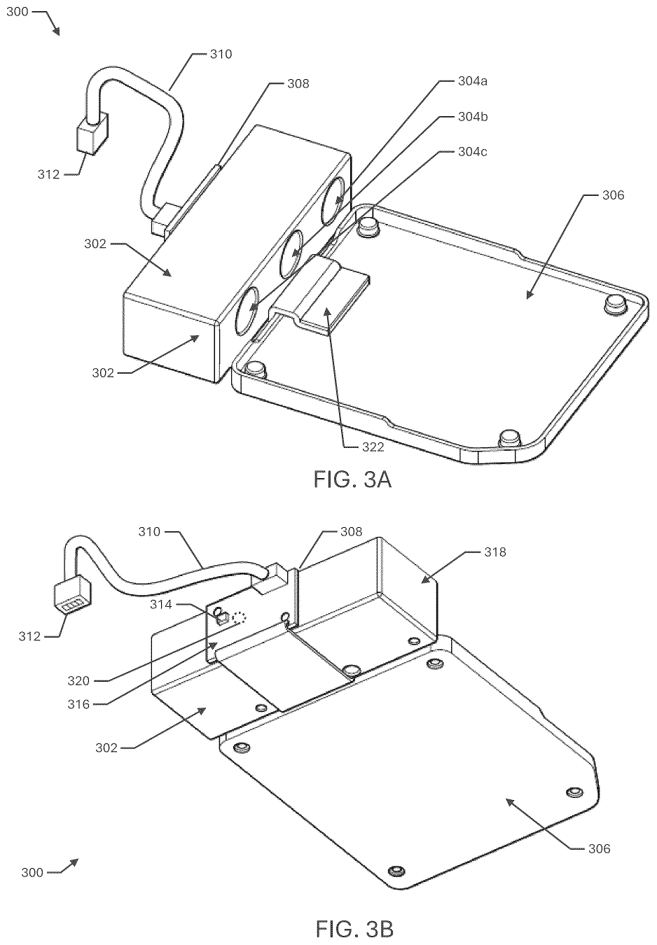

FIGS. 3A and 3B illustrate another example of a manifold assembly 300 that includes an integrated circuit for measuring manifold temperature and detecting leaks in liquid-cooled servers, in accordance with this disclosure. The manifold assembly 300 (e.g., the inlet manifold assembly 102a and the outlet manifold assembly 102b illustrated in FIG. 1, the manifold assembly 200) includes a manifold 302 having ports 304a, 304 b, and 304 c. In other implementations, the manifold 302 may have two ports or more than three ports. In this example, Port 304a is connected to tubing (not shown) that either routes liquid coolant into the manifold 302 from a source external to a server (e.g., server 100 illustrated in FIG. 1) if the manifold 302 is implemented as an inlet manifold or out of the server to a return external to the server if the manifold 302 is implemented as an outlet manifold. The ports 304b and 304c are connected to tubing that routes the coolant to or from chips, respective to the manifold being an inlet manifold or outlet manifold, internal to the server. In other implementations, the functionality of ports 304a, 304b, and 304c may be interchanged.

The manifold assembly 300 also includes a leak container 306 (e.g., the leak containers 106a and 106b illustrated in FIG. 1) and a PCB assembly 308 (e.g., the PCB assemblies 108a and 108b illustrated in FIG. 1). The PCB assembly 308 can be connected to a motherboard via a single cable 310 (e.g., the cables 110a and 110b illustrated in FIG. 1) and a connector 312 (e.g., the connectors 112a and 112b illustrated in FIG. 1).

The PCB assembly 308 illustrated in FIGS. 3A and 3B include an integrated circuit 314, a rigid portion 316 attached on one side of the manifold 302, and a flexible portion 318 that wraps around an underneath side of the manifold 302. In some cases, the PCB assembly 308 may only have a rigid portion or may only have a flexible portion. Alternatively, the flexible portion 318 may be replaced with a cable (e.g., a ribbon cable connected to the rigid portion 316). The flexible portion 318 (or the ribbon cable in some examples) may be routed in a slot (not shown) on the manifold 302 configured such that the flexible portion 318 is flush with the outer surface of the manifold 302.

The integrated circuit includes a temperature sensor 320 in contact with the manifold, configured to detect a temperature of the manifold (and thus a temperature of the coolant liquid), and a communication system disposed on the rigid portion 316, and a leak detections sensor 322 disposed on the flexible portion 318. The temperature sensor 320 is configured to detect a temperature of the manifold. The leak detection sensor 322 is configured to detect whether a liquid exists in an area proximate to the leak container 306. The communication system is configured to communicate the temperature of the manifold 302 and whether liquid exists in the area.

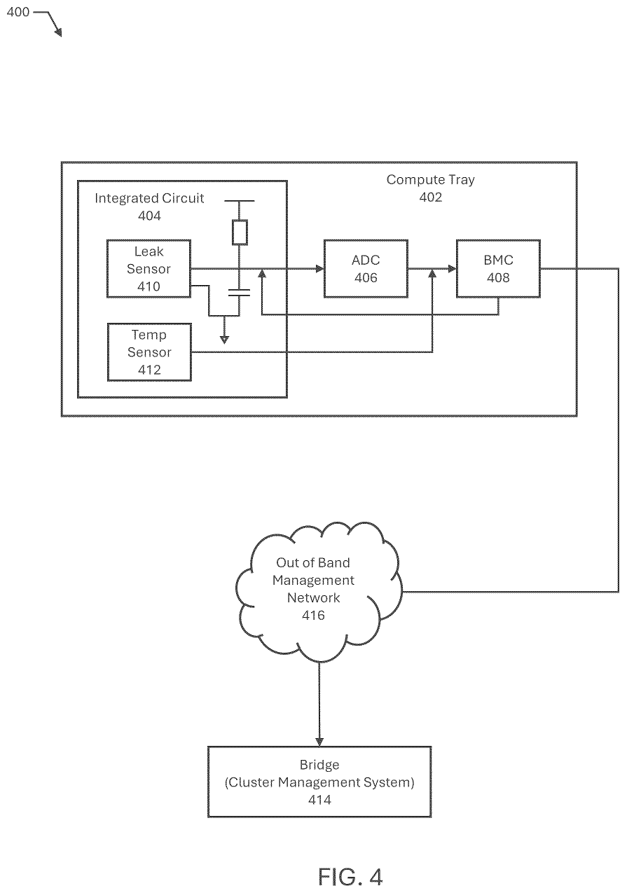

FIG. 4 illustrates an example of a schematic 400 of an integrated circuit 404 for measuring manifold temperature and detecting leaks in liquid-cooled servers. As illustrated in FIG. 4 a server has a compute tray 402 (or a switch tray for a switch). The compute tray 402 includes the integrated circuit 404, an analog-to-digital converter (ADC) 406, and a BMC 408. In this example, the integrated circuit 404 includes a leak sensor 410 and a temperature sensor 412. The ADC 406 may convert analog signals from the leak sensor 410 to digital signals. The signals for the integrated circuit, including the analog signal from the leak sensor 410 and the digital signal from the temperature sensor 412 are communicated to the ADC 406 and BMC 408 through a single cable coupled to a system bus of the server. Thus, analog signals (e.g., from the leak sensor 410), may be converted to digital signs prior to being transmitted/communicated. In this case, the BMC 408 transfers signals and instructions between the integrated circuit 404 and a Bridge 414 (e.g., cluster management system) via an out of band network 416. In other cases, the BMC 408 may communicate signals to and from another type of monitoring system and/or by other wired or wireless means.

### Example Flowchart of a Liquid Control System

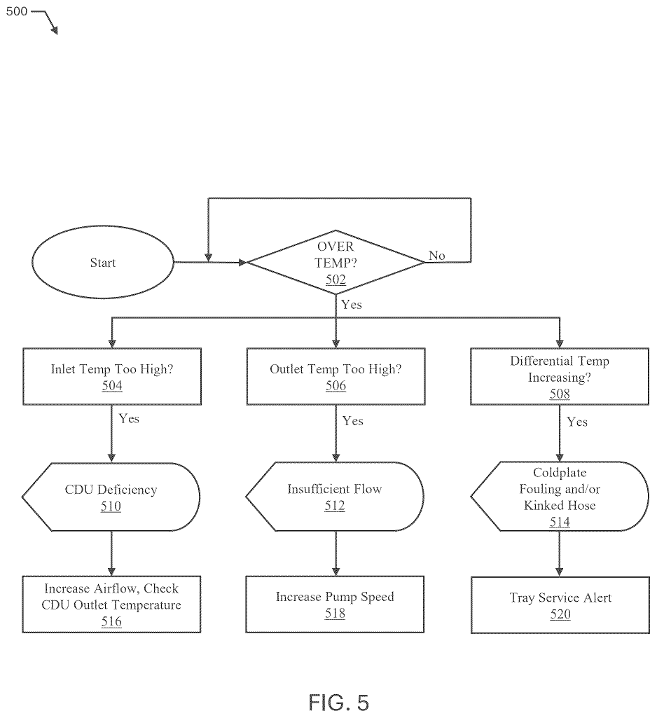

FIG. 5 illustrates an example process flow of root-cause analysis of high-temperature situations in liquid-cooled servers coupled to an integrated circuit for measuring manifold temperature and detecting leaks in liquid-cooled servers, in accordance with this disclosure. In some cases, the liquid control system (e.g., a monitoring system, a liquid control module) may be included internal to a server, and in other cases, the liquid control system may be remote to the server. Additionally, in any case, the liquid control system may be a hardware system, a software system, or a combined hardware/software system. In many current cooling systems, an OVER TEMP condition indicating that one or more chips or an internal temperature of a server is critically hot, but other information may not be available. As illustrated in FIG. 5, the liquid control system not only may receive an OVER TEMP indication but may determine from sensor data the reason for the OVER TEMP indication and a solution to remedy the OVER TEMP condition.

At 502, the liquid control system monitors the sensors as described herein. If an OVER TEMP indication is received, the liquid control system further analyzes the sensor data. Three conditions are possible in this example: is the inlet temperature too high; is the outlet temperature too high; and is the differential temperature between the inlet temperature and outlet temperature increasing.

At 504, if the inlet temperature is too high (e.g., above an inlet threshold temperature), it may be indicative of a CDU deficiency 510. At 516, The liquid control system may cause airflow within the server to increase, for example, by increasing the internal fan speeds or by other methods. The liquid control system may also check the outlet temperature of the CDU. This outlet temperature is indicative of the temperature of the coolant that is being delivered to the server cooling system. A high CDU outlet temperature may reveal a problem with the CDU or other external components.

At 506, if the outlet temperature is too high (e.g., above an outlet threshold temperature), it may be a result of insufficient coolant flow 512. At 518, one option that may be pursued is to increase the speed of the pump or pumps used to feed the coolant to the server cooling system.

At 508, if the differential temperature is increasing and/or if it is above a threshold differential temperature, there may be a restriction in coolant flow. For example, there may be cold plate fouling or there may be a kinked hose or tube in the cooling system 514. At 520, if this condition is determined by the liquid control system, it can trigger a tray service alert. In this situation, maintenance personnel are made aware that one of these issues is likely to exist within the server cooling system and can take steps to rectify the failure.

### Example Liquid Control System

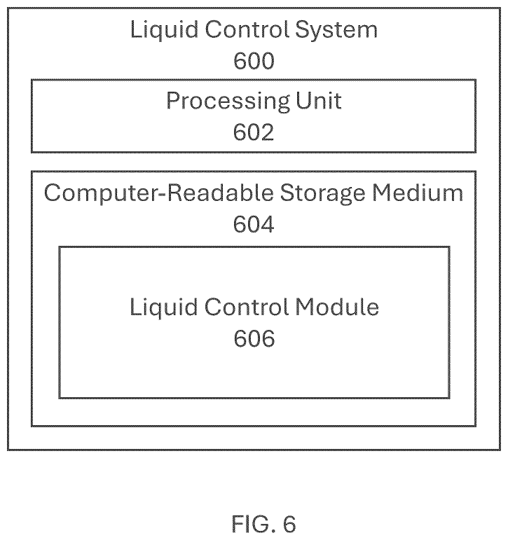

FIG. 6 illustrates an example of a liquid control system 600 coupled to an integrated circuit for measuring manifold temperature and detecting leaks in liquid-cooled servers. The liquid control system 600 may be integrated within a server (e.g., as part of a BMC) or a separate device. The liquid control system 600 includes at least one processing unit 602 and a computer-readable storage medium 604. The liquid control system 600 may be internal or external to any liquid-cooled server.

The processing unit 602 (e.g., one or more of an application processor, central processor (CPU), graphics processor (GPU), microprocessor, digital-signal processor (DSP), or controller) executes a liquid control module 606 stored within the computer-readable storage medium 604 (e.g., a non-transitory storage devices such as a hard drive, SSD, flash memory, read-only memory (ROM), EPROM, or EEPROM) to cause the liquid control system 600 to perform the techniques described herein.

The liquid control module 606 may act upon (e.g., create, receive, modify, delete, transmit, or display) data (e.g., application data, module data, sensor data, or I/O data) sent or received from an integrated circuit as described herein. Although shown as being within the computer-readable storage medium 604, the liquid control module 606 may be a completely hardware solution, a completely software solution, or a combined hardware/software solution. In all cases, the liquid control module 606 may implement the process flow illustrated in FIG. 5. Additionally, the liquid control module 606 may monitor coolant leakage as determined from a leak detection sensor as part of the integrated circuit, as described in this document.

### EXAMPLES

Example 1: An integrated circuit comprising: a mounting portion configured to attach at least a portion of the integrated circuit to a manifold; a temperature sensor configured to detect a temperature of the manifold; a leak detection sensor configured to detect whether a liquid exists in an area proximate a component coupled with the manifold; and a communication system configured to communicate the temperature of the manifold and whether the liquid exists in the area.

Example 2: The integrated circuit of example 1, wherein the mounting portion is a portion of a PCB.

Example 3: The integrated circuit of example 2, wherein: the PCB has a rigid portion; and the temperature sensor and the communication system are disposed on the rigid portion of the PCB.

Example 4: The integrated circuit of example 2 or 3, wherein: the PCB has a flexible portion; and the leak detection sensor is disposed on the flexible portion.

Example 5: The integrated circuit of example 4, wherein the flexible portion is routed through a slot on the manifold, the slot configured such that the flexible portion is flush to the manifold.

Example 6: The integrated circuit of example 2, wherein the temperature sensor is disposed on the PCB.

Example 7: The integrated circuit of example 5, wherein: the leak detection sensor is remote to the PCB; and the leak detection sensor is communicatively coupled with the PCB via a cable.

Example 8: The integrated circuit of example 7, wherein the cable is routed through a slot on the manifold, the slot configured such that the cable is flush to the manifold.

Example 9: The integrated circuit of any previous example, wherein the leak detection sensor is configured to be disposed proximate one or more ports of the manifold.

Example 10: The integrated circuit of example 9, wherein the leak detection sensor is configured to be disposed in a tray proximate one or more ports of the manifold.

Example 11: The integrated circuit of any previous example, wherein the leak detection sensor is configured to be disposed on a different side of the manifold as the temperature sensor.

Example 12: The integrated circuit of any previous example, wherein the communication system is configured to communicate the temperature of the manifold and whether the liquid exists in the area to a liquid control system.

Example 13: The integrated circuit of example 12, wherein: a signal from the leak detection sensor is an analog signal; the integrated circuit includes an analog-to-digital converter (ADC); and the analog signal is converted to a digital signal by the ADC prior to being communicated to the liquid control system.

Example 14: The integrated circuit of any previous example, wherein the communication system is configured to communicate the temperature of the manifold and whether the liquid exists in the area via a single cable.

Example 15: A server comprising: a plurality of manifold assemblies, each of the manifold assemblies including: a manifold including: a first port; and one or more second ports in communication with the first port; and an integrated circuit attached to the manifold, the integrated circuit including: a temperature sensor configured to detect a temperature of the manifold; a leak detection sensor configured to detect whether a liquid exists in an area proximate the manifold; and a communication system configured to communicate the temperature of the manifold and whether the liquid exists in the area.
Example 16: The server of example 15, wherein the manifold assemblies comprise an inlet manifold assembly and an outlet manifold assembly.

Example 17: A liquid control system comprising: a processing system configured to: receive an inlet temperature from an inlet integrated circuit attached to an inlet manifold within a server; receive an outlet temperature from an outlet integrated circuit attached to an outlet manifold within the server; receive a processing system temperature of a processing system within the server; and responsive to determining that the processing system temperature is above a threshold temperature, determine a possible cause of the processing system temperature being above the threshold temperature based on at least one of the inlet temperature or the outlet temperature.

Example 18: The liquid control system of example 17, wherein the processing system is further configured to, responsive to determining that the inlet temperature is above an inlet threshold temperature: cause airflow to increase within the server; or check an outlet temperature of a coolant distribution unit (CDU) providing coolant to the server.

Example 19: The liquid control system of example 17 or 18, wherein the processing system is further configured to, responsive to determining that the outlet temperature is above an outlet threshold temperature, cause an increase in flowrate of a coolant flowing through the server.

Example 20: The liquid control system of example 17, 18, or 19, wherein the processing system is configured to, responsive to determining that the processing system temperature is above the threshold temperature: determine a differential temperature between the inlet temperature and the outlet temperature; and responsive to determining that the differential temperature is above a threshold differential temperature, determine the possible cause of the processing system temperature to be a restriction in flow between the inlet manifold and the outlet manifold.

### CONCLUSION

The terminology used herein is for the purpose of describing particular embodiments only and is not intended to be limiting of this disclosure. As used herein, the singular forms “a”, “an” and “the” are intended to include the plural forms as well, unless the context clearly indicates otherwise. It will be further understood that the terms “includes”, “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Further, the terms up, upper, down, lower, above, below, left, right, forward, rearward, and the like are intended to be understood in the context of the representations described and illustrated above so that a wearable device may have such an orientation in reference to the frame or to various elements as supported by the frame or as illustrated in the drawing figures.

The corresponding structures, materials, acts, and equivalents of all means or step plus function elements, if any, in the claims below are intended to include any structure, material, or act for performing the function in combination with other claimed elements as specifically claimed. The description of the present disclosure has been presented for purposes of illustration and description but is not intended to be exhaustive or limited to this disclosure in the form disclosed. Many modifications and variations will be apparent to those of ordinary skill in the art without departing from the scope and spirit of this disclosure. The various embodiments were chosen and described in order to best explain the principles of this disclosure and the practical application, and to enable others of ordinary skill in the art to understand this disclosure for various embodiments with various modifications as are suited to the particular use contemplated.

What is claimed is:

1. An integrated circuit comprising:
a mounting portion configured to attach at least a portion of the integrated circuit to a manifold;
a temperature sensor configured to detect a temperature of the manifold;
a leak detection sensor configured to detect whether a liquid exists in an area proximate a component coupled with the manifold; and
a communication system configured to communicate the temperature of the manifold and whether the liquid exists in the area.

2. The integrated circuit of claim 1, wherein the mounting portion is a portion of a printed circuit board (PCB).

3. The integrated circuit of claim 2, wherein:
the PCB has a rigid portion; and
the temperature sensor and the communication system are disposed on the rigid portion of the PCB.

4. The integrated circuit of claim 2, wherein:
the PCB has a flexible portion; and
the leak detection sensor is disposed on the flexible portion.

5. The integrated circuit of claim 4, wherein the flexible portion is routed through a slot on the manifold, the slot configured such that the flexible portion is flush to the manifold.

6. The integrated circuit of claim 2, wherein the temperature sensor is disposed on the PCB.

7. The integrated circuit of claim 6, wherein:
the leak detection sensor is remote to the PCB; and
the leak detection sensor is communicatively coupled with the PCB via a cable.

8. The integrated circuit of claim 7, wherein the cable is routed through a slot on the manifold, the slot configured such that the cable is flush to the manifold.

9. The integrated circuit of claim 1, wherein the leak detection sensor is configured to be disposed proximate one or more ports of the manifold.

10. The integrated circuit of claim 9, wherein the leak detection sensor is configured to be disposed in a tray proximate one or more ports of the manifold.

11. The integrated circuit of claim 1, wherein the leak detection sensor is configured to be disposed on a different side of the manifold as the temperature sensor.

12. The integrated circuit of claim 1, wherein the communication system is configured to communicate the temperature of the manifold and whether the liquid exists in the area to a liquid control system.

13. The integrated circuit of claim 12, wherein:
a signal from the leak detection sensor is an analog signal;
the integrated circuit includes an analog-to-digital converter (ADC); and
the analog signal is converted to a digital signal by the ADC prior to being communicated to the liquid control system.

14. The integrated circuit of claim 1, wherein the communication system is configured to communicate the temperature of the manifold and whether the liquid exists in the area via a single cable.

15. A server comprising:
a plurality of manifold assemblies, each of the manifold assemblies including:
a manifold including:
a first port; and
one or more second ports in communication with the first port; and
an integrated circuit attached to the manifold, the integrated circuit including:
a temperature sensor configured to detect a temperature of the manifold;
a leak detection sensor configured to detect whether a liquid exists in an area proximate the manifold; and
a communication system configured to communicate the temperature of the manifold and whether the liquid exists in the area.

16. The server of claim 15, wherein the manifold assemblies comprise an inlet manifold assembly and an outlet manifold assembly.

17. A liquid control system comprising:
a processing system configured to:
receive an inlet temperature from an inlet integrated circuit attached to an inlet manifold within a server;
receive an outlet temperature from an outlet integrated circuit attached to an outlet manifold within the server;
receive a processing system temperature of a processing system within the server; and
responsive to determining that the processing system temperature is above a threshold temperature, determine a possible cause of the processing system temperature being above the threshold temperature based on at least one of the inlet temperature or the outlet temperature.

18. The liquid control system of claim 17, wherein the processing system is further configured to, responsive to determining that the inlet temperature is above an inlet threshold temperature:
cause airflow to increase within the server; or
check an outlet temperature of a coolant distribution unit (CDU) providing coolant to the server.

19. The liquid control system of claim 17, wherein the processing system is further configured to, responsive to determining that the outlet temperature is above an outlet threshold temperature, cause an increase in flowrate of a coolant flowing through the server.

20. The liquid control system of claim 17, wherein the processing system is configured to, responsive to determining that the processing system temperature is above the threshold temperature:
determine a differential temperature between the inlet temperature and the outlet temperature; and
responsive to determining that the differential temperature is above a threshold differential temperature, determine the possible cause of the processing system temperature to be a restriction in flow between the inlet manifold and the outlet manifold.
